(19) United States
(12) Patent Application Publication
(10) Pub. No.: US 2005/0121757 A1
(43) Pub. Date: Jun. 9, 2005

(54) Integrated circuit package overlay

(76) Inventor: Charles A. Gealer, Phoenix, AZ (US)

Correspondence Address: BUCKLEY, MASCHOFF, TALWALKAR LLC, 5 ELM STREET, NEW CANAAN, CT, 06840, US

(21) Appl. No.: 10/728,245

(22) Filed: Dec. 4, 2003

(51) Int. Cl. H01L 23/02

(52) U.S. Cl. 257/678; 438/106

(57) ABSTRACT

A system may include an integrated circuit package substrate, a plurality of integrated circuit die attached to the integrated circuit package substrate, and a stiffener strip attached to the integrated circuit package substrate and surrounding two or more of the plurality of integrated circuit die.

### BACKGROUND

Many systems exist for housing an integrated circuit (IC) die. These systems may electrically couple an IC die to various external elements, and may provide thermal and physical protection to the IC die. Some systems use a mold cap to physically protect an IC die.

A mold cap may comprise a stiff material that encapsulates the IC die while the IC die sits on an IC package. Fabrication of a system including a mold cap may be costly and time-consuming. Moreover, reliability and/or quality of such a system may be compromised by interactions between a mold compound used to create the mold cap, the IC die, and underfill material residing between the IC die and the IC package.

### BRIEF DESCRIPTION OF THE DRAWINGS

FIG. 1 is a side cross-sectional view of an apparatus according to some embodiments.

FIG. 2 is a top view of a stiffener strip according to some embodiments.

FIG. 3 is a diagram of a process to fabricate the FIG. I apparatus according to some embodiments.

FIG. 4 is a top view of an IC package substrate according to some embodiments.

FIG. 5 is a bottom view of an IC die according to some embodiments.

FIG. 6 is a top view of an IC package substrate having a plurality of IC die attached thereto according to some embodiments.

FIG. 7 is a top view of a stiffener strip, an IC package substrate, and a plurality of IC die according to some embodiments.

FIG. 8 is a side cross-sectional view of a stiffener strip, an IC package substrate, and a plurality of IC die according to some embodiments.

FIG. 9 is a side cross-sectional view of a stiffener strip, an IC package substrate, and a plurality of IC die according to some embodiments.

FIG. 10 is a top view of a stiffener strip, an IC package substrate, and a plurality of IC die according to some embodiments.

FIG. 11 is a top view of an apparatus according to some embodiments.

FIG. 12 is a side cross-sectional view of an apparatus according to some embodiments.

FIG. 13 is a diagram of a system according to some embodiments.

### DETAILED DESCRIPTION

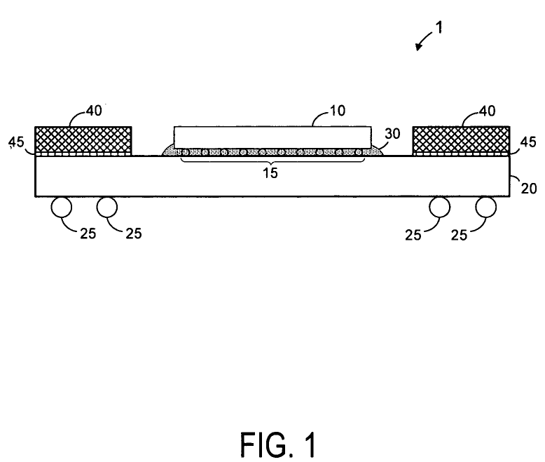

FIG. 1 is a cross-sectional side view of apparatus 1 according to some embodiments. Apparatus 1 includes IC die 10 coupled to IC package 20. IC die 10 includes integrated electrical devices and may be fabricated using any suitable material and fabrication techniques. IC die 10 may provide one or more functions. In some embodiments, IC die 10 comprises a microprocessor, a network processor, or a transceiver having a silicon substrate.

Electrical contacts 15 are coupled to IC die 10 and may be electrically coupled to the electrical devices that are integrated into IC die 10. Electrical contacts 15 are also coupled to electrical contacts (not shown) of substrate 20. In some embodiments, die 10 is electrically coupled to substrate 20 via wirebonds in addition to or as an alternative to electrical contacts 15. Substrate 20 may comprise an IC package, a circuit board, or other substrate. Substrate 20 may therefore comprise any ceramic, organic, and/or other suitable material.

Substrate 20 comprises solder balls 25 for carrying power and I/O signals between elements of apparatus 1 and external devices. For example, solder balls 25 may be mounted directly to a motherboard (not shown) or onto an interposer that is in turn mounted directly to a motherboard. Alternative interconnects such as through-hole pins may be used instead of solder balls 25 to mount apparatus 1 to a motherboard, a socket, or another substrate.

Underfill material 30 encapsulates the electrical coupling between the die and the substrate and may. therefore protect the coupling from exposure to environmental hazards. Underfill material 30 may be used to assist the mechanical coupling between IC die 10 and IC package 20. For example, electrical contacts 15 may experience mechanical stress when heated due to a difference between the coefficient of thermal expansion (CTE) of IC die 10 and the CTE of IC package 20. Underfill material 30 may address this mismatch by distributing the stress away from the connections.

Stiffener portion 40 may also reduce the mechanical stress experienced by electrical connections 15. Stiffener portion 40 may cause IC package 20 to deform less in response to environmental and operational conditions than IC package 20 would otherwise deform in the absence of stiffener portion 40. According to some embodiments, stiffener portion 40 causes an area of IC package 20 to which IC die 10 is coupled to deform more similarly to IC die 10 in response to certain environmental and operational conditions. Although not apparent from the FIG. 1 cross-sectional view, stiffener portion 40 surrounds IC die 10 according to some embodiments.

Stiffener portion 40 may comprise any suitable material including but not limited to a temperature-resistant polymer. Stiffener portion 40 is coupled to IC package 20 using adhesive 45. According to some embodiments, stiffener portion 40 is coupled to IC package 20 without the use of adhesive 45. Stiffener portion 40 may protect the edges of IC package 20, and may provide a contact surface for handling apparatus 1.

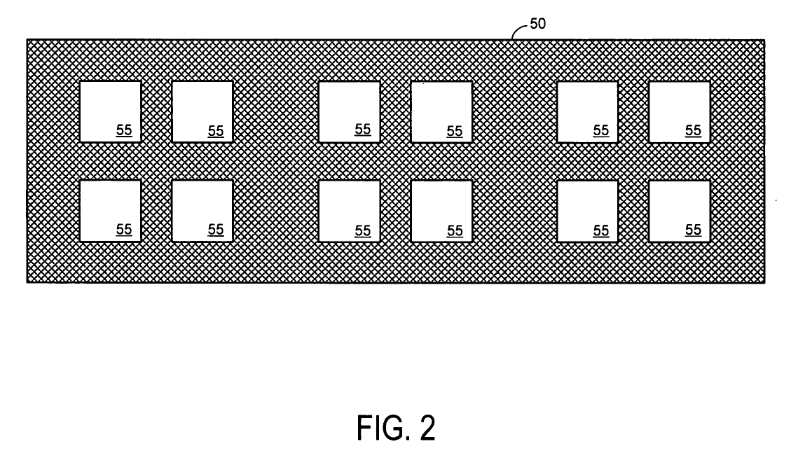

FIG. 2 is a top view of stiffener strip 50 according to some embodiments. Stiffener strip 50 may be comprised of any currently- or hereafter-known suitable material, including those described above with respect to stiffener portion 40. Selection of the material may depend on the particular fabrication process used in conjunction with stiffener strip 50. One such process is described below.

Stiffener strip 50 defines a plurality of openings 55. As will be described below, positions and sizes of openings 55 may correspond to positions and sizes of IC die in a matrix array package (MAP) configuration.

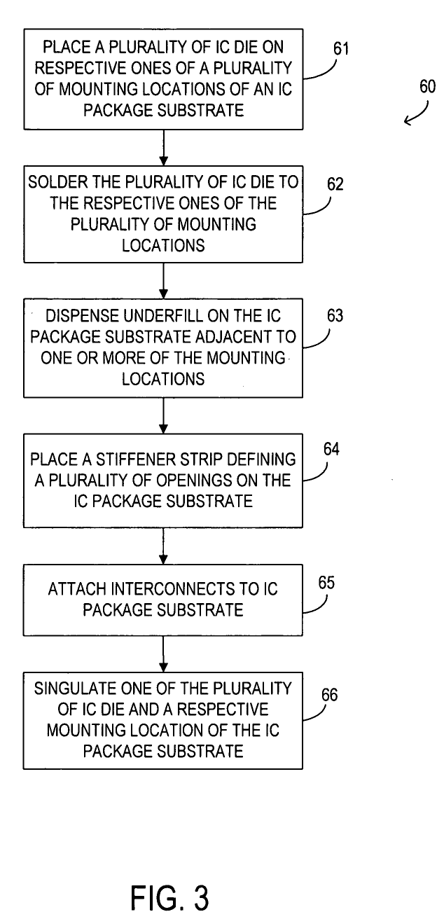

FIG. 3 is a diagram of process 60 to fabricate apparatus 1 according to some embodiments. Process 60 may be executed by one or more devices, and all or a part of process 60 may be executed manually. Process 60 may be executed by an entity different from an entity that manufactures IC die 10.

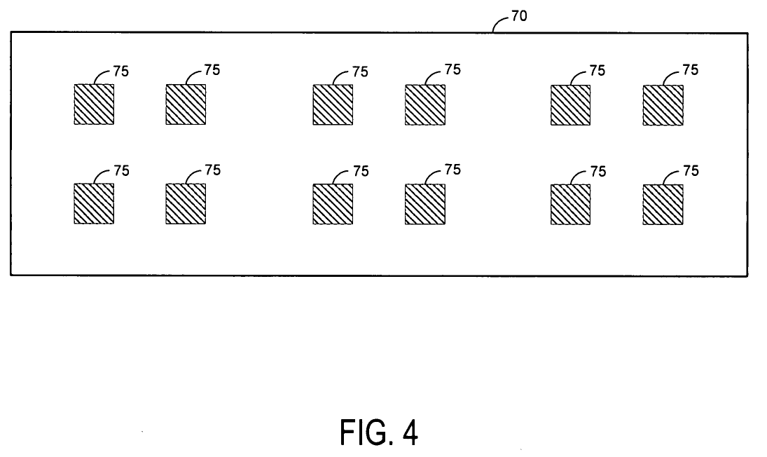

Initially, at 61, a plurality of IC die are placed on respective ones of a plurality of mounting locations of an IC package substrate. Descriptions of an IC package substrate and an IC die are now provided in order to explain some embodiments of 61. FIG. 4 shows IC package substrate 70 and mounting locations 75 according to some embodiments. IC package substrate 70 may be composed of any suitable IC package material, including but not limited to an organic laminated glass-weave polymer.

Mounting locations 75 are disposed in a MAP configuration. Mounting locations 75 may comprise any type of electrical contacts for electrically coupling an IC die to routing vias and electrical traces within IC package substrate 70. According to some embodiments, IC package substrate 70 and mounting locations 75 may be fabricated using any currently- or hereafter-known MAP fabrication method.

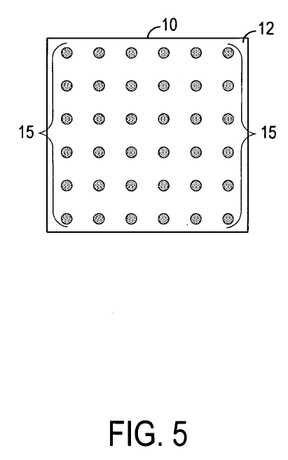

FIG. 5 shows first side 12 of IC die 10 according to some embodiments. First side 12 of IC die 10 includes electrical contacts 15. Electrical contacts 15 may be electrically coupled to the electrical devices that are integrated into IC die 10. The electrical devices may reside between a substrate of IC die 10 and electrical contacts 15 in a “flip-chip” arrangement. In some embodiments, such a substrate resides between the electrical devices and electrical contacts 15.

Electrical contacts 15 may comprise any device-to-substrate interconnect technology, including but not limited to Controlled Collapse Chip Connect (C4) solder bumps, and gold and/or nickel-plated copper contacts fabricated upon IC die 10. In this regard, electrical contacts 15 may be recessed under, flush with, or extending above first side 12 of IC die 10.

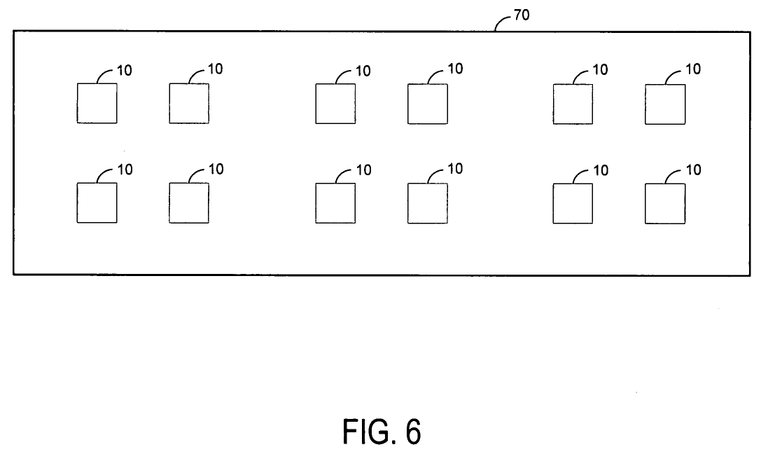

At 61, the plurality of die 10 may be placed on respective ones of mounting locations 75 using a pick-and-place machine. FIG. 6 is a top view of IC package substrate 70 after a plurality of IC die 10 are placed thereon at 61. Next, at 62, electrical contacts 15 are soldered to respective contacts of mounting locations 75. Such soldering may be accomplished using conventional reflow techniques.

Underfill material is dispensed on IC package substrate 70 adjacent to one or more mounting locations 75 at 63. The dispensed underfill material may comprise a capillary flow underfill material according to some embodiments. Generally, capillary flow underfill material is placed next to an IC die-substrate interface and is “pulled” into the interface by surface energy and/or capillary action. Energy may then be applied to the underfill material to transform the material into a protective inert polymer.

Stiffener strip 50 is then placed on IC package substrate 70 at 64. Stiffener strip 50 may be removed from a stack of stiffener strips and placed on IC package substrate 70 by a pick-and-place machine. The side of stiffener strip 50 to contact IC package substrate 70 may be coated with an adhesive to assist adhering strip 50 to IC package substrate 70. Such an adhesive may comprise a partially-cured, solid epoxy.

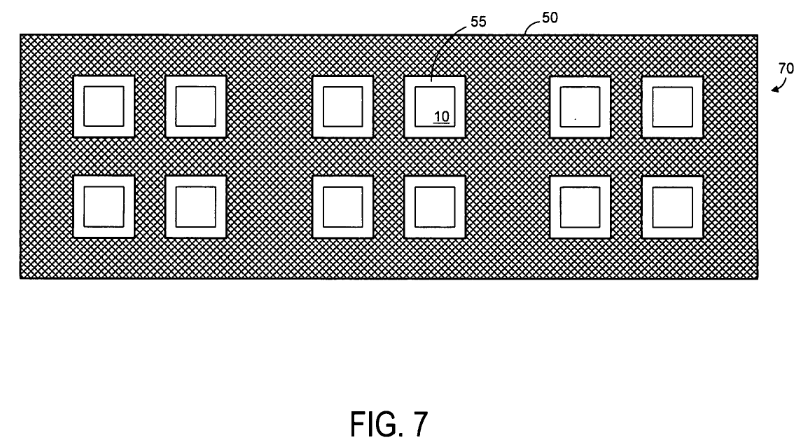

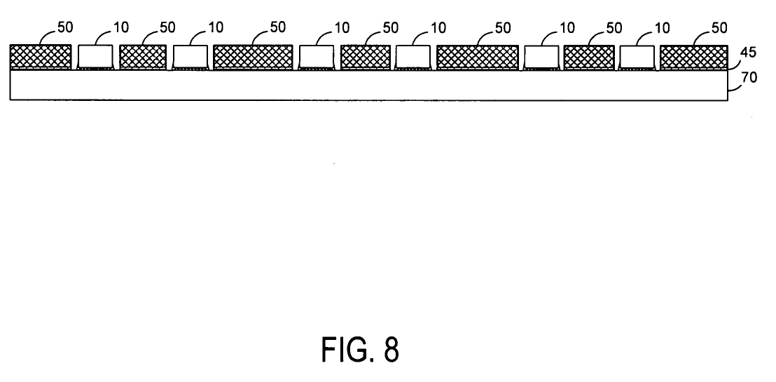

FIG. 7 shows stiffener strip 50 as placed on IC package substrate 70 according to some embodiments. Openings 55 correspond to the locations of IC die 10 and therefore the plurality of IC die 10 are visible through openings 55 in the FIG. 7 view. FIG. 8 is a cross-sectional side view further illustrating the arrangement of IC package substrate 70, IC die 10, and stiffener strip 50 after 64 and according to some embodiments. FIG. 8 shows adhesive 45 disposed between stiffener strip 50 and IC package substrate 70.

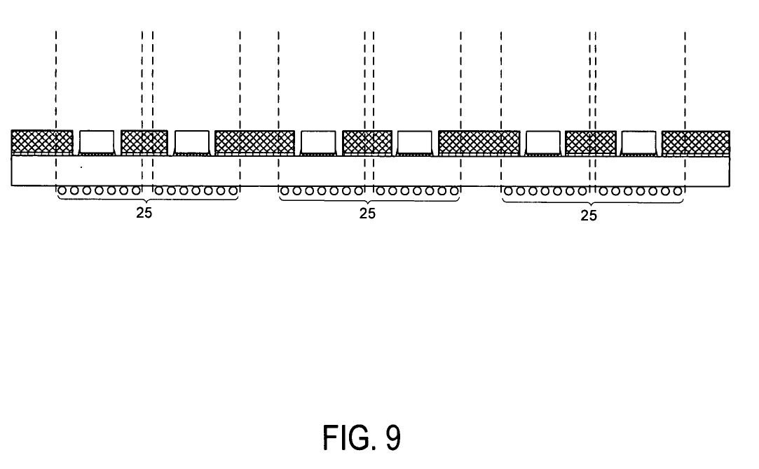

Interconnects are attached to IC package substrate 70 at 65. As shown in FIG. 9, such interconnects may comprise solder balls 25. Solder balls 25 may be attached by turning substrate 70 upside down, placing solder balls 25 at appropriate locations, and reflowing solder balls 25. Such reflowing may also serve to fully cure adhesive 45 depending on adhesive 45 and the reflow temperature profile.

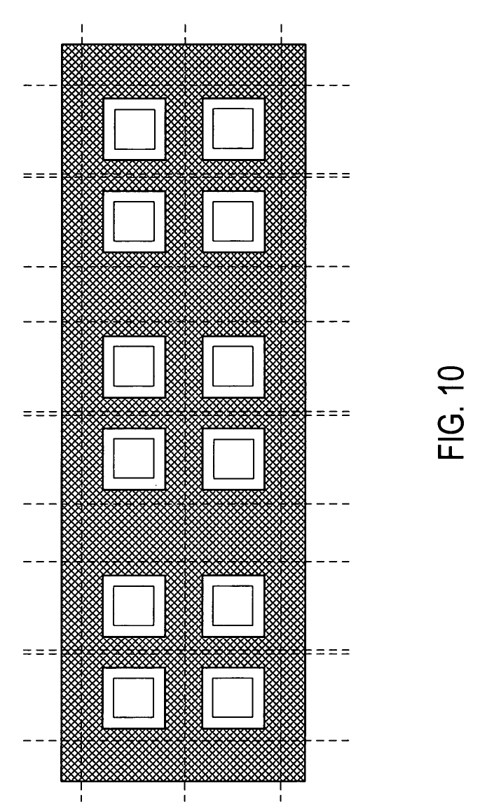

The dashed lines of FIG. 9 represent where stiffener strip 50 may be cut at 66 in order to singulate one or more of IC die 10 along with a respective portion of IC package substrate 70. FIG. 10 is a top view of stiffener strip 50 further showing a cutting pattern according to some embodiments. Singulation at 66 may proceed using any currently- or hereafter-known methods, including saw singulation.

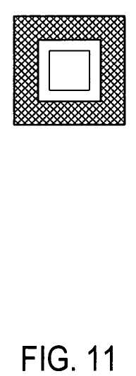

A top view of a singulated IC die 10 and its respective mounting location of IC package substrate 70 is shown in FIG. 11. The FIG. 11 apparatus is identical to apparatus 1 of FIG. 1 according to some embodiments.

In some embodiments of process 60, stiffener strip 50 may be placed on IC package substrate before 61, 62, or 63. These embodiments may require a designer to ensure that openings 55 are large enough to allow underfill material to be properly dispensed around IC die 10.

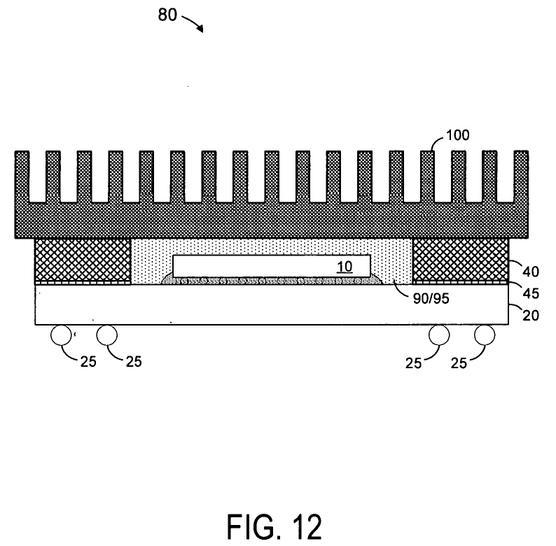

FIG. 12 illustrates apparatus 80 according to some embodiments. The elements of apparatus 80 may be identical to similarly-numbered elements of apparatus 1. As shown, stiffener portion 40 extends farther from IC package 20 than does die 10. Stiffener portion 40 and IC package 20 thereby define well 90 in which IC die 10 is disposed. According to some embodiments, well 90 is filled with thermally-conductive material 95.

Moreover, heat sink 100 is coupled to stiffener portion 40 and is in contact with thermally-conductive material 95. Heat sink 100 may comprise any currently- or hereafter-known passive or active heat sink. A thermally-conductive paste or other material may be disposed between thermally-conductive material 95 and heat sink 100, and/or between stiffener portion 40 and heat sink 100. Such an arrangement may improve the conductivity of heat away from die 10.

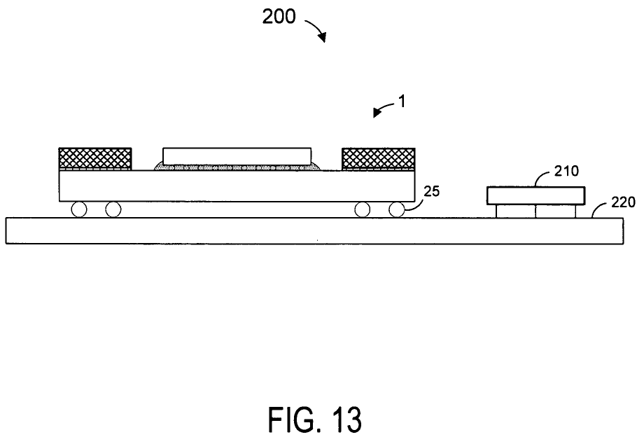

FIG. 13 is a cross-sectional side view of system 200 according to some embodiments. System 200 may comprise components of a server platform. System 200 includes apparatus 1 as described above, memory 210 and motherboard 220. Apparatus 1 may comprise a microprocessor.

Motherboard 220 may electrically couple memory 210 to apparatus 1. More particularly, motherboard 220 may comprise a memory bus (not shown) that is electrically coupled to solder balls 25 and to memory 210. Memory 210 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

1. An apparatus comprising:
an integrated circuit package substrate;
a plurality of integrated circuit die attached to the integrated circuit package substrate; and
a stiffener strip attached to the integrated circuit package substrate and surrounding two or more of the plurality of integrated circuit die.

2. An apparatus according to claim 1, further comprising:
underfill material disposed between the plurality of integrated circuit die and the integrated circuit package substrate.

3. An apparatus comprising:
an integrated circuit package;
an integrated circuit die coupled to the integrated circuit package; and
a stiffener portion coupled to the integrated circuit package and surrounding the integrated circuit die.

4. An apparatus according to claim 3, further comprising:
underfill material disposed between the integrated circuit die and the integrated circuit package.

5. An apparatus according to claim 3, wherein the stiffener portion and the integrated circuit package define a well in which the integrated circuit die is disposed, the apparatus further comprising:
thermally-conductive material disposed in the well and in contact with the integrated circuit die.

6. An apparatus according to claim 5, further comprising:
a heat sink coupled to the stiffener portion and in contact with the thermally-conductive material.

7. A method comprising:
placing a plurality of integrated circuit die on respective ones of a plurality of mounting locations of an integrated circuit package substrate; and
placing a stiffener strip defining a plurality of openings on the integrated circuit package substrate, wherein the plurality of integrated circuit die and the plurality of mounting locations are disposed in respective ones of the plurality of openings.

8. A method according to claim 7, further comprising:
soldering the plurality of integrated circuit die to the respective mounting locations.

9. A method according to claim 8, further comprising:
dispensing underfill material on the integrated package substrate adjacent to one or more of the mounting locations.

10. A method according to claim 7, further comprising:
singulating one of the plurality of integrated circuit die and a respective mounting location of the integrated package substrate.

11. A system comprising:
a microprocessor comprising:
an integrated circuit package;
an integrated circuit die coupled to the integrated circuit package; and
a stiffener portion coupled to the integrated circuit package and surrounding the integrated circuit die; and
a double data rate memory electrically coupled to the microprocessor.

12. A system according to claim 11, wherein the stiffener portion and the integrated circuit package define a well in which the integrated circuit die is disposed, the microprocessor further comprising:
thermally-conductive material disposed in the well and in contact with the integrated circuit die.

13. A system according to claim 12, the microprocessor further comprising:
a heat sink coupled to the stiffener portion and in contact with the thermally-conductive material.

14. A system according to claim 1 1, further comprising:
a motherboard electrically coupled to the microprocessor and to the memory.
